(19) United States
(12) Patent Application Publication
(10) Pub. No.: US 2024/0321545 A1
(43) Pub. Date: Sep. 26, 2024

(54) SEMICONDUCTOR DEVICE

(71) Applicants: Kabushiki Kaisha Toshiba, Tokyo (JP); Toshiba Electronic Devices & Storage Corporation, Tokyo (JP)

(72) Inventor: Hiroko NAKAMURA, Yokohama Kanagawa (JP)

(21) Appl. No.: 18/458,075

(22) Filed: Aug. 29, 2023

(30) Foreign Application Priority Data
Mar. 22, 2023 (JP) 2023-046062

(51) Int. Cl. H01J 37/147

(52) U.S. Cl. CPC H01J 37/1472; H01J 37/3174; H01J 2237/151

(57) ABSTRACT

A semiconductor device includes: a first chip having a first substrate surface, a second substrate surface provided on a side opposite to the first substrate surface, and a plurality of first through holes, a plurality of charged particle beams passing through the first through holes; a second chip provided on the first chip and having a third substrate surface facing the second substrate surface, a fourth substrate surface, and a plurality of second through holes provided on the first through holes, the charged particle beams passing through the second through holes; a plurality of first electrodes provided on the first substrate surface so as to be adjacent to the first through holes; a plurality of second electrodes provided on the first substrate surface; a plurality of third electrodes provided on the fourth substrate surface so as to be adjacent to the second through holes; and a plurality of fourth electrodes provided on the fourth substrate surface, wherein the first electrodes are a first pair of electrodes for deflecting the charged particle beams, the third electrodes are a second pair of electrodes for deflecting the charged particle beams, the second electrode and the fourth electrode are an additional electrode pattern other than the first pair of electrodes and the second pair of electrodes for deflecting the charged particle beams, and an electrode pattern formed by the first electrode and the second electrode on the first substrate surface and an electrode pattern formed by the third electrode and the fourth electrode on the fourth substrate surface are not symmetrical with respect to opposite substrate surfaces of the two chips.

### CROSS-REFERENCE TO RELATED APPLICATION

This application is based upon and claims the benefit of priority from Japanese Patent Application No. 2023-046062, filed on Mar. 22, 2023, the entire contents of which are incorporated herein by reference.

### FIELD

Embodiments described herein relate generally to a semiconductor device.

### BACKGROUND

A charged particle beam apparatus, especially an apparatus using electron beams, is used as a mask or wafer drawing apparatus in lithography.

In addition, the charged particle beam apparatus is used as a microscope for observing the surface shape of substances, such as a scanning electron microscope and a helium (He) ion microscope. In addition, by using the microscope function of the charged particle beam apparatus, the charged particle beam apparatus is also used as a defect inspection apparatus for observing defects occurring in semiconductor wafer products, masks used in semiconductors, liquid crystal displays, and the like.

In addition, recently, multi-beam apparatuses capable of using multiple beams have also come into use to increase speed. In such a multi-beam apparatus, for example, electron beams emitted from an electron gun pass through a shaping aperture to form multi-beams, blanking control is performed, each unshielded beam is demagnified by an optical system, and a mask image is demagnified, deflected by a deflector, and emitted to a desired position on a sample.

### BRIEF DESCRIPTION OF THE DRAWINGS

FIG. 1 is a schematic cross-sectional view of an electron beam drawing apparatus according to a first embodiment;

FIG. 2 is a schematic diagram showing the principle of a blanking aperture array according to the first embodiment;

FIG. 3 is a schematic diagram of a semiconductor device as a first form of the first embodiment;

FIG. 4 is a schematic diagram of a semiconductor device as a second form of the first embodiment;

FIG. 5 is a schematic diagram of a semiconductor device as a third form of the first embodiment;

FIG. 6 is a schematic diagram of a semiconductor device as a comparative form of the first embodiment;

FIGS. 7A and 7B are schematic plan views of a semiconductor device as a comparative form of the first embodiment;

FIG. 8 is a schematic plan view of the semiconductor device according to the first embodiment;

FIGS. 9A and 9B are schematic cross-sectional views of the semiconductor device according to the first embodiment;

FIGS. 10A and 10B are schematic plan views of a main part of the semiconductor device according to the first embodiment;

FIG. 11 is a schematic cross-sectional view of a semiconductor device according to a second embodiment;

FIG. 12 is a schematic cross-sectional view of a semiconductor device according to a third embodiment;

FIG. 13 is a schematic diagram of a main part of a semiconductor device as a comparative form of a fourth embodiment;

FIG. 14 is a schematic diagram of a main part of a semiconductor device as a comparative form of the fourth embodiment;

FIG. 15 is a schematic diagram of a semiconductor device according to the fourth embodiment;

FIG. 16 is a schematic diagram of the semiconductor device according to the fourth embodiment;

FIG. 17 is a schematic diagram of the semiconductor device according to the fourth embodiment;

FIG. 18 is a schematic diagram of the semiconductor device according to the fourth embodiment;

FIG. 19 is a schematic diagram of the semiconductor device according to the fourth embodiment; and

FIG. 20 is a schematic diagram of the semiconductor device according to the fourth embodiment.

### DETAILED DESCRIPTION

A semiconductor device of embodiments includes: a first chip having a first substrate surface, a second substrate surface provided on a side opposite to the first substrate surface, and a plurality of first through holes, a plurality of charged particle beams passing through the first through holes; a second chip provided on the first chip and having a third substrate surface facing the second substrate surface, a fourth substrate surface, and a plurality of second through holes provided on the first through holes, the charged particle beams passing through the second through holes; a plurality of first electrodes provided on the first substrate surface so as to be adjacent to the first through holes; a plurality of second electrodes provided on the first substrate surface; a plurality of third electrodes provided on the fourth substrate surface so as to be adjacent to the second through holes; and a plurality of fourth electrodes provided on the fourth substrate surface. The first electrodes are a first pair of electrodes for deflecting the charged particle beams. The third electrodes are a second pair of electrodes for deflecting the charged particle beams. The second electrode and the fourth electrode are additional electrode patterns other than the first pair of electrodes and the second pair of electrodes for deflecting the charged particle beams. An electrode pattern formed by the first electrode and the second electrode on the first substrate surface and an electrode pattern formed by the third electrode and the fourth electrode on the fourth substrate surface are not symmetrical with respect to opposite substrate surfaces of the two chips.

Hereinafter, embodiments will be described with reference to the diagrams. In addition, in the diagrams, the same or similar elements are denoted by the same or similar reference numerals.

In this specification, the same or similar members are denoted by the same reference numerals, and the repeated descriptions thereof may be omitted.

In this specification, in order to show the positional relationship of components and the like, the upper direction of the diagram is described as “upper” and the lower direction of the diagram is described as “lower”. In this specification, the concepts of “upper” and “lower” do not necessarily indicate the relationship with the direction of gravity.

### First Embodiment

A semiconductor device of embodiments includes: a first chip having a first substrate surface, a second substrate surface provided on a side opposite to the first substrate surface, and a plurality of first through holes, a plurality of charged particle beams passing through the first through holes; a second chip provided on the first chip and having a third substrate surface facing the second substrate surface, a fourth substrate surface, and a plurality of second through holes provided on the first through holes, the charged particle beams passing through the second through holes; a plurality of first electrodes provided on the first substrate surface so as to be adjacent to the first through holes; a plurality of second electrodes provided on the first substrate surface; a plurality of third electrodes provided on the fourth substrate surface so as to be adjacent to the second through holes; and a plurality of fourth electrodes provided on the fourth substrate surface. The first electrodes are a first pair of electrodes for deflecting the charged particle beams. The third electrodes are a second pair of electrodes for deflecting the charged particle beams. The second electrode and the fourth electrode are additional electrode patterns other than the first pair of electrodes and the second pair of electrodes for deflecting the charged particle beams. An electrode pattern formed by the first electrode and the second electrode on the first substrate surface and an electrode pattern formed by the third electrode and the fourth electrode on the fourth substrate surface are not symmetrical with respect to opposite substrate surfaces of the two chips.

In addition, the semiconductor device of embodiments includes: a plurality of first pads provided on the first substrate surface and electrically connected to the first electrodes; and a plurality of second pads provided on the fourth substrate surface, electrically connected to the third electrodes, and not overlapping the first pads when viewed from above. In addition, the semiconductor device of embodiments includes a support electrically connected to the first pads and the second pads by using a plurality of wires.

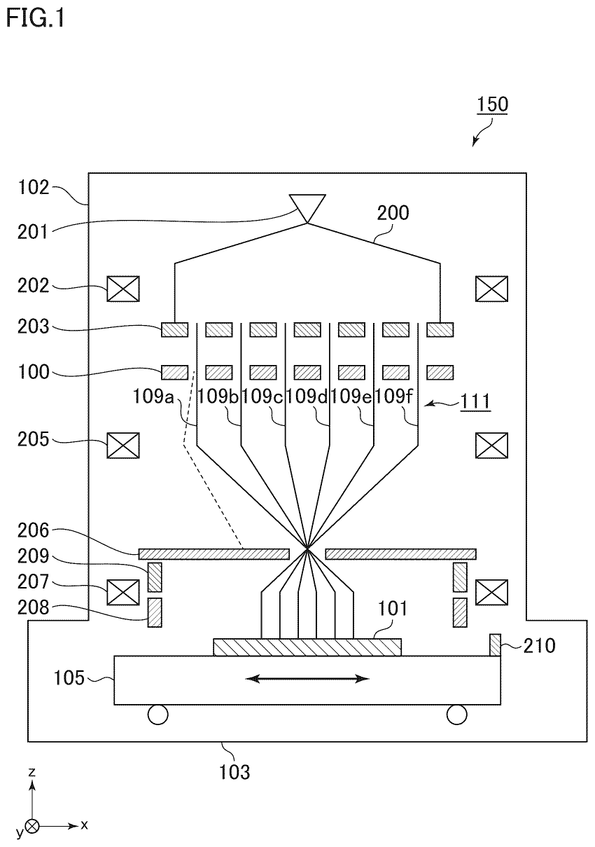

FIG. 1 is a schematic cross-sectional view of an electron beam drawing apparatus 150 of embodiments. The electron beam drawing apparatus 150 is an example of a multi-charged particle beam drawing apparatus or a charged particle beam drawing apparatus.

A semiconductor device 100 of embodiments is used, for example, as a blanking aperture array (deflector) of the electron beam drawing apparatus 150. In addition, the application of the semiconductor device 100 is not limited to this.

The electron beam drawing apparatus 150 includes an electron lens barrel 102 (multi-electron beam column) and a drawing chamber 103. An electron gun 201, an illumination lens 202, a shaping aperture array 203, the semiconductor device 100 (blanking aperture array), a demagnifying lens 205, a limiting aperture member 206, an objective lens 207, a main deflector 208, and a sub-deflector 209 are arranged inside the electron lens barrel 102.

Here, an X axis, a Y axis perpendicular to the X axis, and a Z axis perpendicular to the X axis and the Y axis are defined. It is assumed that the electron gun 201 emits an electron beam 200 in a direction opposite to the Z-axis direction. In addition, it is assumed that a sample 101 is arranged within a plane parallel to the XY plane.

The electron beam 200 emitted from the electron gun 201 illuminates the shaping aperture array 203 almost vertically through the illumination lens 202. Then, the electron beam 200 passes through the opening of the shaping aperture array 203 to form a multi-beam 111. The multi-beam 111 has electron beams 109a, 109b, 109c, 109d, 109e, and 109f. The shape of each electron beam 109 reflects the shape of the opening of the shaping aperture array 203. For example, the shape of each electron beam 109 is rectangular. In addition, although six openings of the shaping aperture array 203 are shown in FIG. 1, the number of openings of the shaping aperture array 203 is not limited to this. Six multi-beams 111 formed by the shaping aperture array 203 are shown in FIG. 1. However, the number of multi-beams 111 formed is not limited. As an example, the openings of the shaping aperture array 203 are arranged in a matrix with 512 openings in each of the X and Y directions.

The semiconductor device 100 is provided below the shaping aperture array 203. The electron beam 109 deflected by the semiconductor device 100 (shown by dotted line) is displaced from the central hole of the limiting aperture member 206 and is blocked by the limiting aperture member 206. On the other hand, the undeflected electron beam 109 passes through the central hole of the limiting aperture member 206. As a result, ON/OFF of the electron beam is controlled.

The electron beam 109 that has passed through the limiting aperture member 206 is focused by the objective lens 207 to form a pattern image with a desired reduction ratio, and is collectively deflected by the main deflector 208 and the sub-deflector 209. Then, the electron beam 109 is emitted to each irradiation position on the sample 101 placed on an XY stage 105. In addition, a mirror 210 for position measurement of the XY stage 105 is arranged on the XY stage 105.

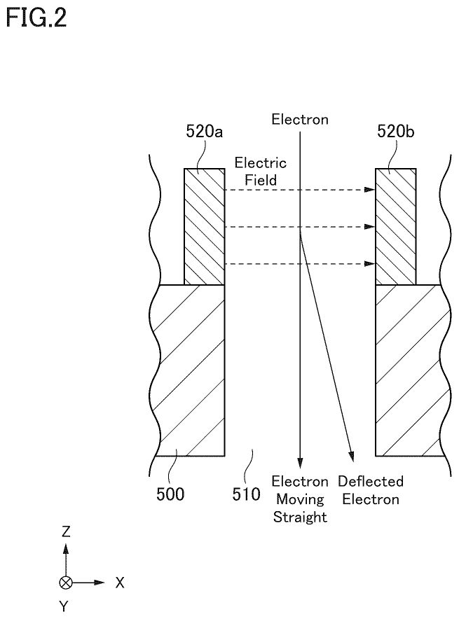

FIG. 2 is a schematic diagram showing the principle of a blanking aperture array of embodiments. A pair of electrodes 520a and 520b are arranged on a substrate 500. For example, a predetermined voltage is applied to the electrode 520b. The predetermined voltage is, for example, about several volts, but is not particularly limited. In addition, the electrode 520a is grounded, for example. As a result, an electric field is generated between the electrodes 520a and 520b, and electrons passing through a through hole 510 are deflected to become deflected electrons. Voltage application is performed by a switching element provided in the substrate 500, for example. This voltage is applied between the electrodes 520a and 520b through, for example, a multi-layer wiring (not shown) provided in the substrate 500.

Here, for example, a complementary metal-oxide-semiconductor (CMOS) element is used as the switching element. In order to increase the switching speed, the voltage used for the CMOS element is being reduced. For this reason, the difference in voltage applied between the electrodes 520a and 520b is reduced. Therefore, the deflection amount of electrons is reduced. In order to avoid this, it is preferable to increase the height of the electrode in the Z direction. However, if the height of the electrode is increased, there is a problem that it is difficult to form the electrode.

By forming two half-height electrodes and arranging the two chips up and down instead of forming a tall electrode in one chip, it becomes easy to form electrodes, and a sufficient amount of charged particle beam deflection can be obtained.

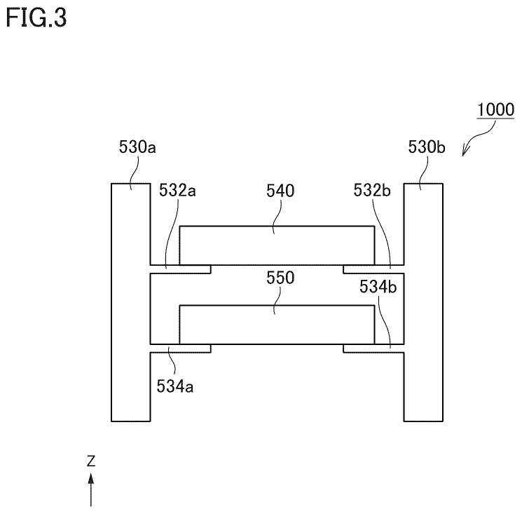

FIG. 3 is a schematic diagram of a semiconductor device 1000 as a first form of embodiments. The semiconductor device 1000 supports an LSI chip 540 and an LSI chip 550 using a support 530 having support portions 532 and 534. According to the semiconductor device 1000, the height of an electrode in the Z direction is increased by arranging electrodes (not shown) formed on the LSI chip 540 and electrodes (not shown) formed on the LSI chip 550 in the Z direction.

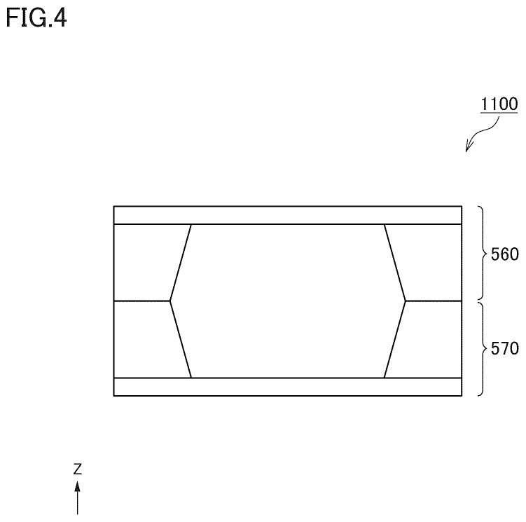

FIG. 4 is a schematic diagram of a semiconductor device 1100 as a second form of embodiments. By bonding an LSI chip 560 and an LSI chip 570 to each other, the height of an electrode in the Z direction is increased.

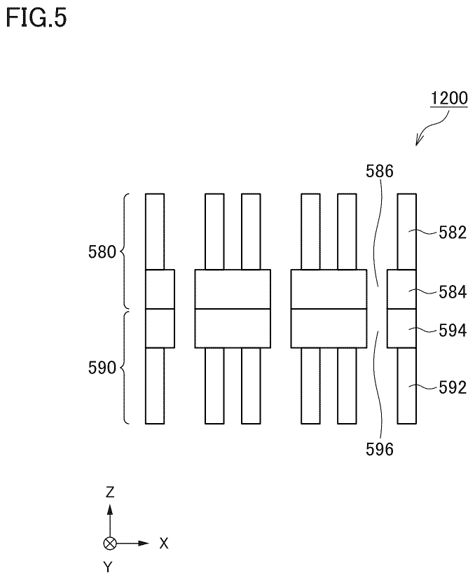

FIG. 5 is a schematic diagram of a semiconductor device 1200 as a third form of embodiments. The semiconductor device 1200 has an LSI chip 580 and an LSI chip 590. The LSI chip 580 has a silicon substrate 584, an electrode 582, and a through hole 586. The LSI chip 590 has a silicon substrate 594, an electrode 592, and a through hole 596. The through hole 586 is disposed on the through hole 596. The silicon substrate 584 and the silicon substrate 594 are each thinned and then silicon-silicon bonded. The low-height electrodes 582 and 592, which are less difficult to make, are arranged in the Z direction. Therefore, tall electrodes that are substantially twice as tall can be easily formed.

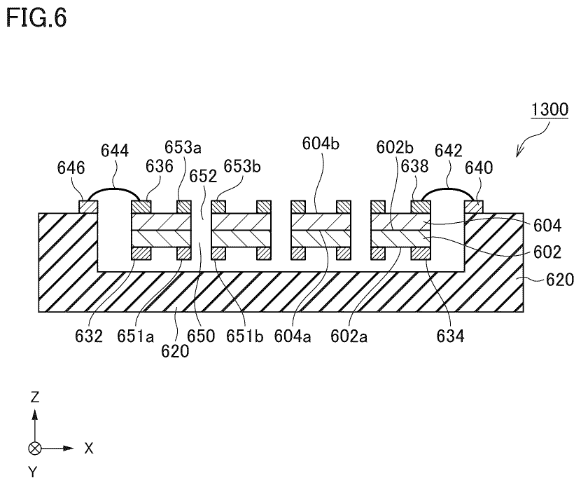

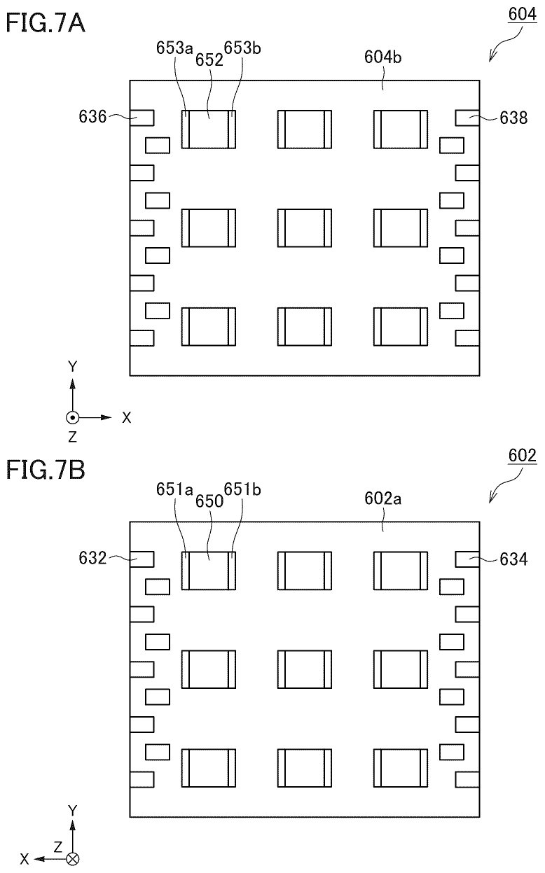

Mounting a semiconductor chip formed as shown in FIG. 5 is considered. FIGS. 6, 7A, and 7B are schematic diagrams of a semiconductor device 1300 as a comparative example of embodiments. FIG. 6 is a schematic cross-sectional view of the semiconductor device 1300 as a comparative example of embodiments. FIG. 7A is a schematic top view of an LSI chip 604 of the semiconductor device 1300 as a comparative example of embodiments. FIG. 7B is a schematic bottom view of an LSI chip 602 of the semiconductor device 1300 as a comparative example of embodiments.

As shown in FIG. 6, the semiconductor device 1300 includes the LSI chip 602, the LSI chip 604, and a support 620. A pad 636 and a pad 638 are provided on an upper surface 604b of the LSI chip 604. The pad 636 is connected to a pad 646 provided on the support 620 by a wire 644. The pad 638 is connected to a pad 640 provided on the support 620 by a wire 642. On the other hand, a pad 632 and a pad 634 are provided on a lower surface 602a of the LSI chip 602. Here, it is assumed that the pad 636 and the pad 632 are provided at the same position when viewed from above (Z direction). In addition, it is assumed that the pad 638 and the pad 634 are provided at the same position when viewed from above (Z direction). In addition, the pads are, for example, bonding pads. In addition, the wires are, for example, bonding wires.

The LSI chip 602 has a plurality of first through holes 650. A plurality of first electrodes 651a are provided on the lower surface 602a of the LSI chip 602 so as to be adjacent to the plurality of first through holes 650, respectively. The plurality of first electrodes 651a are connected to the pads 632 by, for example, multi-layer wirings (not shown) provided inside the LSI chip 602. A predetermined voltage of, for example, about several volts is applied to the plurality of first electrodes 651a. A plurality of second electrodes 651b are provided on the lower surface 602a of the LSI chip 602 so as to be adjacent to the plurality of first through holes 650 and face the plurality of first electrodes 651a, respectively, for example. The plurality of second electrodes 651b are connected to the pads 634 by, for example, multi-layer wirings (not shown) provided inside the LSI chip 602. The plurality of second electrodes 651b are grounded, for example.

The LSI chip 604 has a plurality of second through holes 652. A plurality of third electrodes 653a are provided on the upper surface 604b of the LSI chip 604 so as to be adjacent to the plurality of second through holes 652, respectively. The plurality of third electrodes 653a are connected to the pads 636 by, for example, multi-layer wirings (not shown) provided inside the LSI chip 604. A predetermined voltage of, for example, about several volts is applied to the plurality of third electrodes 653a. A plurality of fourth electrodes 653b are provided on the upper surface 604b of the LSI chip 604 so as to be adjacent to the plurality of second through holes 652 and face the plurality of third electrodes 653a, respectively, for example. The plurality of fourth electrodes 653b are connected to the pads 638 by, for example, multi-layer wirings (not shown) provided inside the LSI chip 604. The plurality of fourth electrodes 653b are grounded, for example.

Here, the plurality of second through holes 652 are provided on the plurality of first through holes 650, respectively. In addition, the upper surface 602b of the LSI chip 602 and the lower surface 604a of the LSI chip 604 are in contact with each other, for example. The upper surface 602b of the LSI chip 602 and the lower surface 604a of the LSI chip 604 are bonded to each other, for example.

The support 620 supports the LSI chip 602 and the LSI chip 604 through the wire 644 and the wire 642. The material and structure of the support 620 are not particularly limited to those shown in FIG. 6.

When the LSI chip 602 and the LSI chip 604 include bonding pads at the same position when viewed from above (Z direction), there is a problem that the wires (bonding wires) connected to the respective pads overlap each other. For this reason, there has been a problem that chips cannot be mounted.

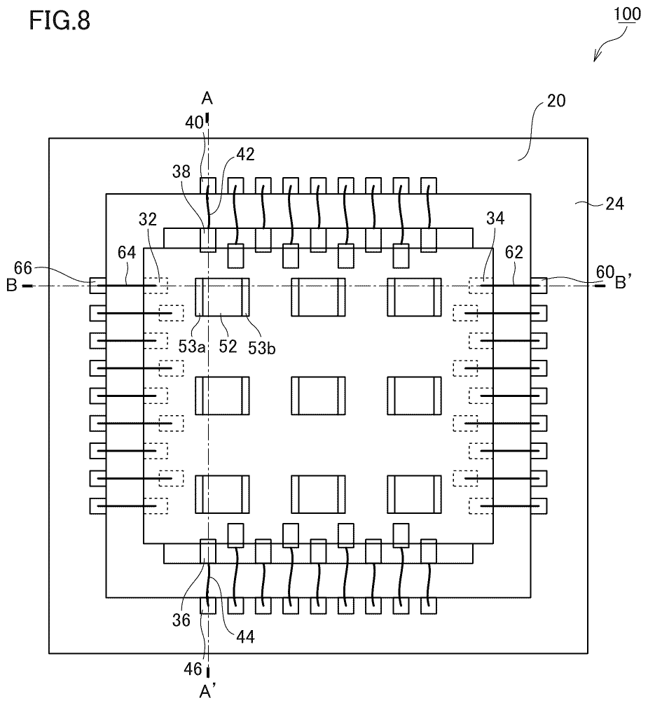

The semiconductor device of embodiments will be described with reference to FIGS. 8, 9A, 9B, 10A, and 10B.

The semiconductor device of embodiments includes a plurality of first pads (an example of a second electrode), which are provided on a first substrate surface and electrically connected to a plurality of first electrodes, and a plurality of second pads (an example of a fourth electrode), which are provided on a fourth substrate surface and electrically connected to a plurality of third electrodes and do not overlap the plurality of first pads when viewed from above. In addition, the semiconductor device of embodiments includes a plurality of first pads, a plurality of second pads, and a support electrically connected by using a plurality of wires.

Here, the first and third electrodes are electrodes for deflecting electron beams, and the second and fourth electrodes are pads.

In addition, a first chip 2 has a rectangular shape. A second chip 4 has a rectangular shape. The plurality of first pads are provided side by side at an end portion along a first direction parallel to a first substrate surface. The plurality of second pads are provided side by side at an end portion along a second direction that is parallel to the fourth substrate surface and crosses the first direction.

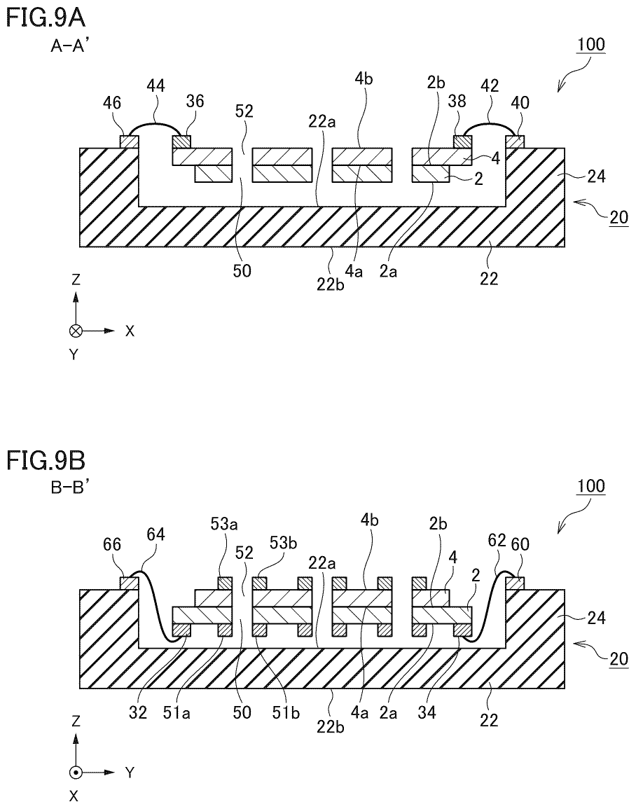

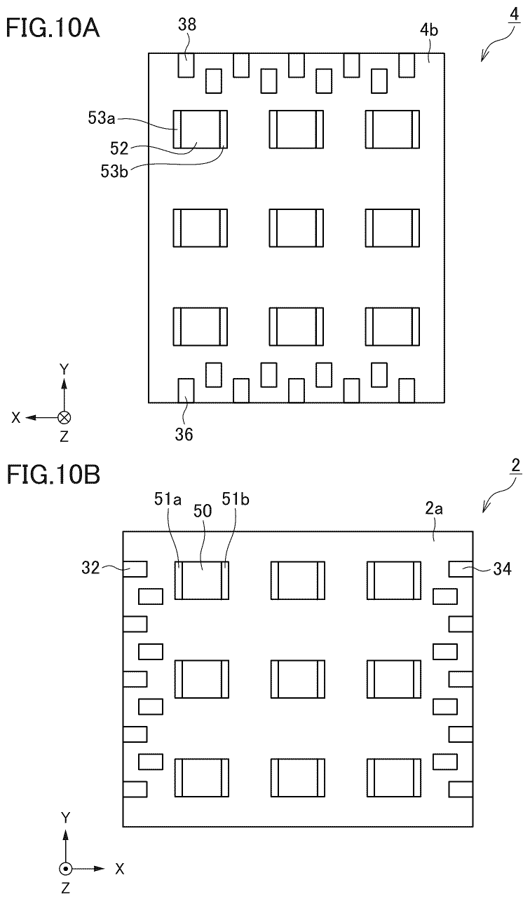

FIG. 8 is a schematic plan view of the semiconductor device 100 of embodiments. FIGS. 9A and 9B are schematic cross-sectional views of the semiconductor device 100 of embodiments. FIGS. 10A and 10B are schematic plan views of a main part of the semiconductor device 100 of embodiments. More specifically, FIG. 9A is a schematic cross-sectional view of the semiconductor device 100 along the A-A′ cross section parallel to the YZ plane. FIG. 9B is a schematic cross-sectional view of the semiconductor device 100 along the B-B′ cross section parallel to the XZ plane. FIG. 10A is a schematic top view of a fourth substrate surface 4b of the second chip 4 of the semiconductor device 100 of embodiments. FIG. 10B is a schematic bottom view of a first substrate surface 2a of the first chip 2 of the semiconductor device 100 of embodiments.

The semiconductor device 100 includes the first chip 2 (for example, shown in FIG. 10B), the second chip 4 (for example, shown in FIG. 10A), and a support 20 (for example, shown in FIG. 8).

Explanations will be given with reference to FIGS. 10A, 10B, and 9B. The first chip 2 has the first substrate surface 2a and a second substrate surface 2b. The second substrate surface 2b is provided on a side opposite to the first substrate surface 2a. The first substrate surface 2a and the second substrate surface 2b are provided in parallel to the XY plane. A pad 32 and a pad 34 are provided on the first substrate surface 2a of the first chip 2. The pad 32 is connected to a pad 66 provided on the support 20 by a wire 64. The pad 34 is connected to a pad 60 provided on the support 20 by a wire 62.

Explanations will be given with reference to FIGS. 10A, 10B, and 9A. The second chip 4 is provided on the first chip 2. The second chip 4 has a third substrate surface 4a and the fourth substrate surface 4b. The fourth substrate surface 4b is provided on a side opposite to the third substrate surface 4a. The third substrate surface 4a and the fourth substrate surface 4b are provided in parallel to the XY plane. A pad 36 and a pad 38 are provided on the fourth substrate surface 4b of the second chip 4. The pad 36 is connected to a pad 46 provided on the support 20 by a wire 44. The pad 38 is connected to a pad 40 provided on the support 20 by a wire 42.

The first chip 2 and the second chip 4 are, for example, semiconductor chips, respectively. The first chip 2 and the second chip 4 are, for example, LSI chips, respectively.

The pads are, for example, bonding pads. In addition, the wires are, for example, bonding wires.

The second substrate surface 2b and the third substrate surface 4a are in contact with each other. For example, when the first chip 2 and the second chip 4 are semiconductor chips formed using a silicon substrate, the second substrate surface 2b and the third substrate surface 4a are silicon-silicon bonded to each other.

Explanations will be given with reference to FIG. 10B. The first chip 2 has a plurality of first through holes 50. A plurality of first electrodes 51a are provided on the first substrate surface 2a of the first chip 2 so as to be adjacent to the plurality of first through holes 50, respectively. The plurality of first electrodes 51a are connected to the pads 32 by, for example, multi-layer wirings (not shown) provided inside the first chip 2. A predetermined voltage of, for example, about several volts is applied to the plurality of first electrodes 51a. A plurality of second electrodes 51b are provided on the first substrate surface 2a of the first chip 2 so as to be adjacent to the plurality of first through holes 50 and face the plurality of first electrodes 51a, respectively, for example. The plurality of second electrodes 51b are connected to the pads 34 by, for example, multi-layer wirings (not shown) provided inside the first chip 2. The plurality of second electrodes 51b are grounded, for example. The first electrode is (the first electrodes are) a first pair of electrodes for deflecting the charged particle beams. The first pair of electrodes includes a deflection electrode (51a) and a ground electrode (51b).

Explanations will be given with reference to FIG. 10A. The second chip 4 has a plurality of second through holes 52. A plurality of third electrodes 53a are provided on the fourth substrate surface 4b of the second chip 4 so as to be adjacent to the plurality of second through holes 52, respectively. The plurality of third electrodes 53a are connected to the pads 36 by, for example, multi-layer wirings (not shown) provided inside the second chip 4. A predetermined voltage of, for example, about several volts is applied to the plurality of third electrodes 53a. A plurality of fourth electrodes 53b are provided on the fourth substrate surface 4b of the second chip 4 so as to be adjacent to the plurality of second through holes 52 and face the plurality of third electrodes 53a, respectively, for example. The plurality of fourth electrodes 53b are connected to the pads 38 by, for example, multi-layer wirings (not shown) provided inside the second chip 4. The plurality of fourth electrodes 53b are grounded, for example. The third electrode is (the third electrodes are) is a second pair of electrodes for deflecting the charged particle beams. The second pair of electrodes includes a deflection electrode (53a) and a ground electrode (53b).

The pads 32 and the pads 34 of the first chip 2 are provided side by side at the end portions of the first chip 2 in the Y direction, respectively. The end portions in the Y direction are along the X direction. On the other hand, the pads 36 and the pads 38 of the second chip 4 are provided side by side at the end portions of the second chip 4 in the X direction, respectively. The end portions in the X direction are along the Y direction. The pad 32 does not overlap the pad 36 and the pad 38 when viewed from above. In addition, the pad 34 does not overlap the pad 36 and the pad 38 when viewed from above.

As shown in FIG. 9B, the plurality of second through holes 52 are provided on the plurality of first through holes 50, respectively. The second through hole 52 and the first through hole 50 are connected to communicate with each other (in FIG. 8, the first through hole 50 is below the second through hole 52).

As shown in FIGS. 9A and 9B, the support 20 includes a plate portion 22 and a protruding portion 24. The plate portion 22 has a first surface 22a facing the first substrate surface 2a and a second surface 22b provided on a side opposite to the first surface 22a. The protruding portion 24 is provided on the first surface 22a so as to surround the first chip 2 and the second chip 4. The pads 40, 46, 60, and 66 are provided on the protruding portion 24. The support 20 supports the first chip 2 and the second chip 4 through the wires 42, 44, 62, and 64. The material and structure of the support 20 are not particularly limited.

The first chip 2 preferably has a rectangular shape within a plane parallel to the XY plane. The second chip 4 preferably has a rectangular shape within a plane parallel to the XY plane.

In FIG. 8, the first electrode 51a and the second electrode 51b are located below the third electrode 53a and the fourth electrode 53b.

As a modification example of embodiments, for example, the shape of the second chip 4 may be a shape obtained by rotating the shape of the first chip 2 by 90° within the XY plane. Although the deflection amount of the electron beam is √2, only one type of chip is prepared, which is preferable because the manufacturing process is simplified. In this case, the plurality of third electrodes 53a and the plurality of fourth electrodes 53b have shapes obtained by rotating the plurality of first electrodes 51a and the plurality of second electrodes 51b by 90 degrees within a plane parallel to the fourth substrate surface 4b when viewed from above.

According to the semiconductor device of embodiments, as shown in FIG. 8, the pad 32 does not overlap the pads 36 and 38 when viewed from above (Z direction). In addition, the pad 34 does not overlap the pad 36 and the pad 38 when viewed from above. Therefore, it is possible to easily mount the first chip 2 and the second chip 4 on the support 20 for electrical connection by using wires.

According to the semiconductor device of embodiments, it is possible to provide a semiconductor device with easy electrical connection.

### Second Embodiment

Although the pads on the chips are wire-bonded in the first embodiment, an example in which the pads on the first chip are flip-bonded is shown in a second embodiment.

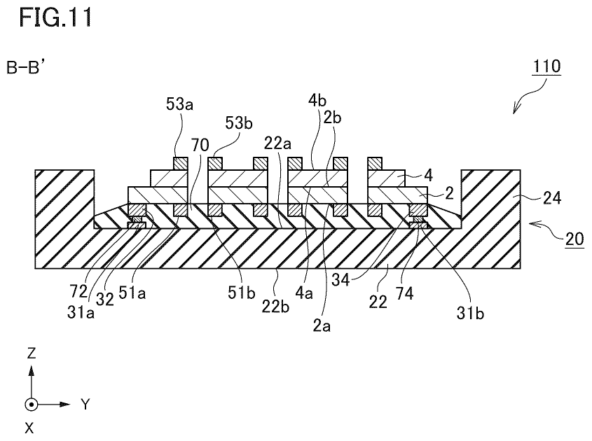

The top view is similar to FIGS. 8, 10A, and 10B, and the semiconductor device is 110 instead of 100. A B-B′ cross section (shown in FIG. 9B) corresponds to FIG. 11, and is a schematic cross-sectional view of the semiconductor device 110 of embodiments. An A-A′ cross section (shown in FIG. 9A) is the same as FIG. 9A. Here, the description of the content overlapping the first embodiment will be omitted.

As shown in FIG. 11, in the semiconductor device of embodiments, the support 20 has a plurality of pads 31 provided on the first surface 22a facing the first substrate surface 2a of the first chip 2. In the semiconductor device of embodiments, the support 20 is electrically connected to the pads 32 and 34, which are provided on the first substrate surface 2a of the first chip 2, through bumps 72 and 74, respectively.

The pad 32 is connected to the pad 31a, which is provided on the first surface 22a of the support 20, through the bump 72. The pad 34 is connected to the pad 31b, which is provided on the first surface 22a of the support 20, through the bump 74. As in FIG. 9A, the second chip 4 is bonded to the pads 36 and 38 on the fourth substrate surface and the pads 46 and 40 on the protruding portion 24 of the support 20 by the wires 44 and 42, respectively.

A sealing resin 70 is provided between the first surface 22a and the first chip 2. By using the sealing resin 70, it is possible to hold the first chip 2 and the second chip 4 more stably. In addition, the sealing resin 70 may contain a filler such as silicon oxide particles or aluminum oxide particles.

According to the semiconductor device of embodiments as well, it is possible to provide a semiconductor device with easy electrical connection.

### Third Embodiment

In the first embodiment, for example, as shown in FIG. 9B, the pads on the lower surface of the first chip 2 are wire-bonded. In embodiments, however, an example of wire bonding by connection to pads provided on the upper surface of the first chip 2 will be described.

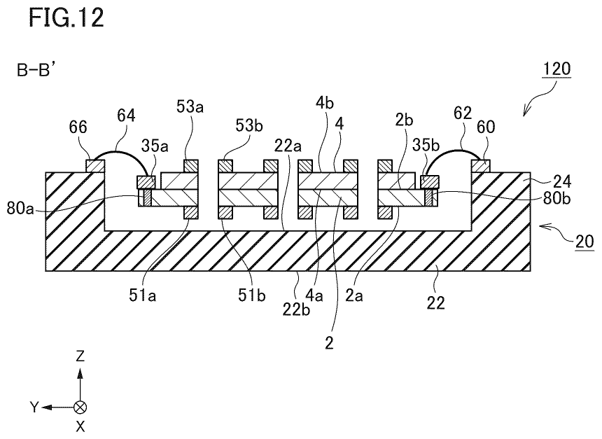

The plan view is similar to FIGS. 8, 10A, and 10B, and the semiconductor device is 120 instead of 100. A B-B′ cross section (shown in FIG. 9B) corresponds to FIG. 12, and is a schematic cross-sectional view of the semiconductor device 120 of embodiments. An A-A′ cross section (shown in FIG. 9A) is the same as FIG. 9A.

Here, the description of the content overlapping the first and second embodiments will be omitted.

As shown in FIG. 12, in the first chip 2 of the semiconductor device of embodiments, a plurality of third pads 35 are provided on the second substrate surface 2b on a side opposite to the first substrate surface 2a. The third pad 35 is electrically connected to a plurality of first electrodes 51a or a plurality of second electrodes 51b through a plurality of vias 80a and 80b penetrating the first chip 2.

As shown in FIG. 12, the support 20 has the pads 60 and 66.

A third pad 35a is connected to the pad 66 on the support by the wire 64, and a third pad 35b is connected to the pad 60 on the support by the wire 62.

The plurality of second pads 36 and 38 which are provided on the fourth substrate surface 4b and electrically connected to the plurality of third electrodes 53a or the plurality of fourth electrodes 53b as shown in FIG. 9A, and the third pad 35 do not overlap each other when viewed from above (this corresponds to the fact that the pads 34 and 32 are formed different sides from the one where the pads 36 and 38 are formed as shown in FIG. 8).

As in FIG. 9A, the pads 36 and 38 on the fourth substrate surface are bonded to the pads 46 and 40 on the protruding portion of the support by the wires 44 and 42, respectively.

When the first chip 2 is formed using a silicon substrate, the vias 80a and 80b are, for example, through-silicon vias.

According to the semiconductor device 120 of embodiments, wire bonding using the wires 62 and 64 can be performed from above the support 20. Therefore, mounting becomes easy.

According to the semiconductor device of embodiments, it is possible to provide a semiconductor device with easy electrical connection.

### Fourth Embodiment

A semiconductor device of embodiments includes: a first chip having a first substrate surface, a second substrate surface provided on a side opposite to the first substrate surface, and a plurality of first through holes, a plurality of charged particle beams passing through the first through holes; a second chip provided on the first chip and having a third substrate surface facing the second substrate surface, a fourth substrate surface, and a plurality of second through holes provided on the first through holes, the charged particle beams passing through the second through holes; a plurality of first electrodes provided on the first substrate surface so as to be adjacent to the first through holes; a plurality of second electrodes provided on the first substrate surface so as to be adjacent to the first through holes; a plurality of third electrodes provided on the fourth substrate surface so as to be adjacent to the second through holes; and a plurality of fourth electrodes provided on the fourth substrate surface so as to be adjacent to the second through holes. The first electrode is (the first electrodes are) a first pair of electrodes for deflecting the charged particle beams. The third electrode is (the third electrodes are) a second pair of electrodes for deflecting the charged particle beams. The second electrode and the fourth electrode are an additional electrode pattern other than the first pair of electrodes and the second pair of electrodes for deflecting the charged particle beams. An electrode pattern formed by the first electrode and the second electrode on the first substrate surface and an electrode pattern formed by the third electrode and the fourth electrode on the fourth substrate surface are not symmetrical with respect to opposite substrate surfaces of the two chips.

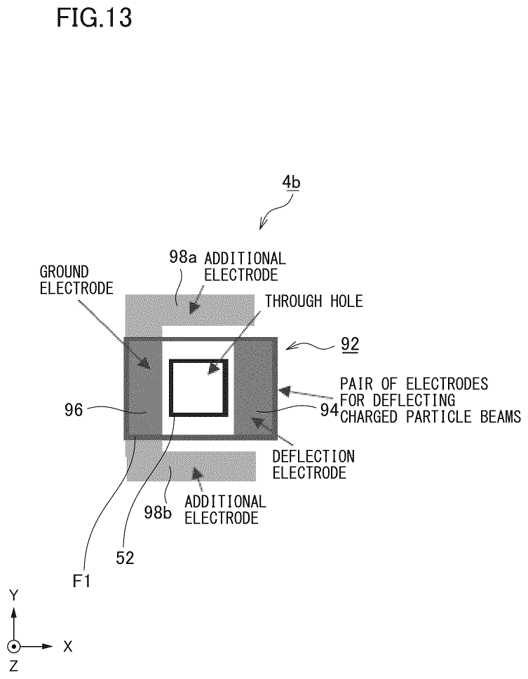

In embodiments, in FIG. 13, the first electrode is (the plurality of third electrodes are) the first pair of electrodes and the third electrode is (the plurality of third electrodes are) the second pair of electrodes (a deflection electrode 94 and a ground electrode 96 surrounded by a frame F1) for deflecting charged particle beams, and the second electrode and the fourth electrode are additional electrodes 98.

As described above, by arranging two chips to double the electrode height, the amount of deflection of the charged particle beam can be doubled. In addition, by adjusting the planar arrangement of the electrode patterns, it is possible to make the drawing pattern less likely to be distorted.

The principle of the multi-charged particle beam drawing apparatus is shown in FIG. 2. Electron beams can be basically deflected with a pair of a deflection electrode and a ground electrode. The pattern surrounded by frame F1 in FIG. 13 shows the planar arrangement of electrode patterns in a comparative example. The deflection electrode 94 and the ground electrode 96 are shown. If there are a pair of electrodes (the deflection electrode 94 and the ground electrode 96) on both sides of the through hole 52 through which charged particle beams pass, the charged particles can be deflected. The pair of electrodes are surrounded by the frame F1 shown for the purpose of explaining embodiments.

However, in addition to this, a ground electrode is often extended and added so as to surround the deflection electrode and the opening. These additional electrodes are formed to eliminate crosstalk. Crosstalk refers to a phenomenon in which, when a pair of electrodes for deflecting charged particle beams are arranged periodically, the electric field also reaches the neighboring through hole. As a result, beams passing through the neighboring through hole are affected and their trajectories are changed. Therefore, crosstalk can be suppressed, for example, by extending the ground electrode to surround the deflection electrode.

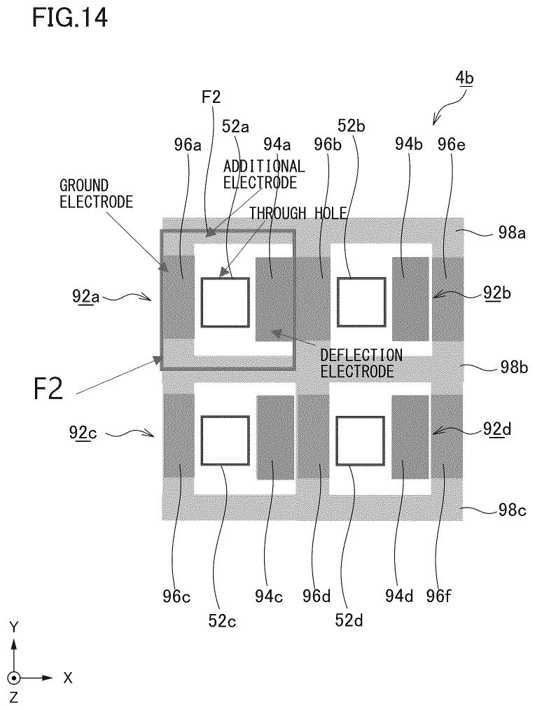

FIG. 14 shows an example of surrounding a deflection electrode. A pair of electrodes are formed by the ground electrode 96 and the deflection electrode (blanking electrode) 94 for deflecting charged particle beams. An additional electrode 98 and the ground electrode 96 are connected to each other to function as a ground electrode. Specifically, an additional electrode 98a and ground electrodes 96a, 96b, and 96e are connected to each other. An additional electrode 98b and ground electrodes 96a, 96b, 96e, 96c, 96d, and 96f are connected to each other. An additional electrode 98c and the ground electrodes 96c, 96d, and 96f are connected to each other.

FIG. 13 shows a structure in which the additional electrode is notched in two adjacent portions, that is, upper right and lower right sides in a unit cell (a portion surrounded by a frame F2, the minimum unit of repetition) in FIG. 14.

This is because the stress increases if the ground electrode surrounds the deflection electrode entirely. In order to reduce the stress, a part of the surrounding electrode pattern is cut away.

However, if notches (spacing portions) are formed in the electrode as described above, the ground electrode and the additional electrode pattern are no longer symmetrical. If the symmetry is lost, the aberration of the lens system of the charged particle beam drawing apparatus is emphasized, or the influence of secondary electrons or scattered electrons becomes asymmetrical. Therefore, a phenomenon that the drawing pattern on the substrate is distorted easily occurs.

When two semiconductor chips overlap each other as shown in FIG. 5, the overlapping ground electrode pattern of the two semiconductor chips on a plane is made symmetrical, because the charged particle beams are affected in opposite directions due to the asymmetry of the two semiconductor chips while passing through the two chips. For this reason, the aberration of the lens system of the charged particle beam drawing apparatus is not emphasized, and the influence of secondary electrons or scattered electrons is canceled. As a result, distortion of the drawing pattern on the substrate can be suppressed.

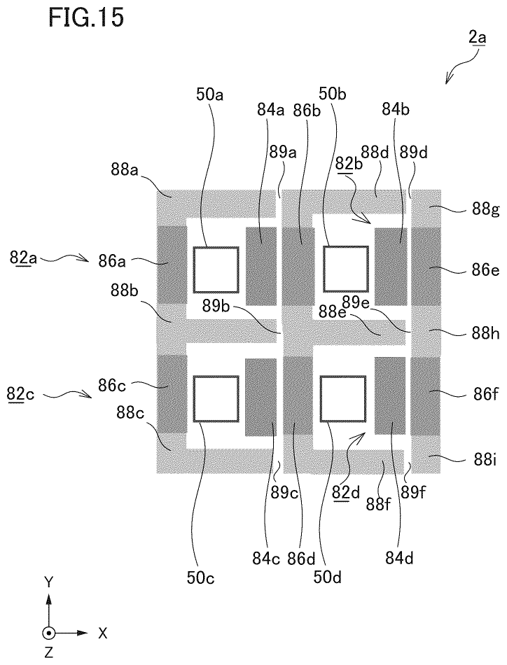

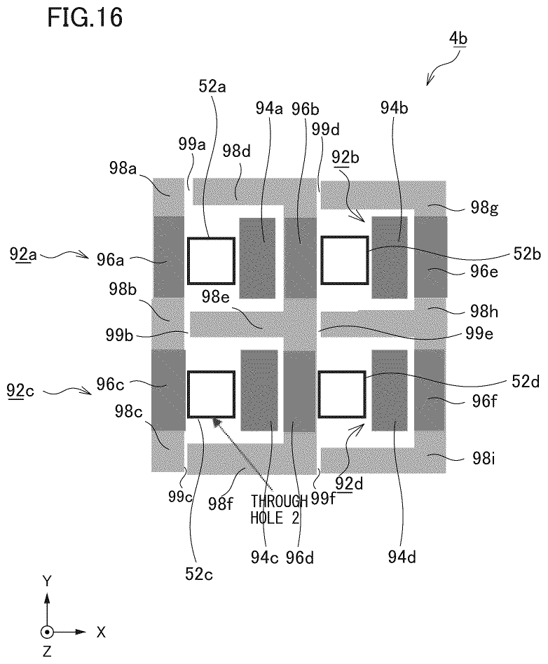

Examples are shown in FIGS. 15 and 16.

When the electrode pattern is viewed from the direction of the arrow on the upper side (from above, from the Z direction) in FIG. 15, a deflection electrode 84 provided on the first substrate surface 2a and the deflection electrode 94 provided on the fourth substrate surface 4b almost overlap each other when the electrode patterns are projected downward. In addition, a ground electrode 86 provided on the first substrate surface 2a and the ground electrode 96 provided on the fourth substrate surface 4b almost overlap each other. In addition, the through hole 50 of the first chip 2 and the through hole 52 of the second chip 4 almost overlap each other. The arrangement of a first spacing portion (notch) 89 of an additional electrode 88 on the first substrate surface 2a and the arrangement of a second spacing portion (notch) 99 of the additional electrode 98 on the fourth substrate surface 4b are different. When the electrode pattern is viewed from the direction of the arrow on the upper side (from above the chip 2) in FIG. 15, a pattern formed by the ground electrode and the additional electrode formed on the first substrate surface 2a and the fourth substrate surface 4b is arranged so as to surround the deflection electrode when the electrode patterns are projected downward. Therefore, in addition to the effect of doubling the amount of deflection by doubling the electrode height, the symmetry of the ground electrode can be maintained. As a result, it is possible to suppress drawing pattern distortion.

In addition, although not shown, an additional electrode 88g extends in the X direction, similarly to an additional electrode 88d. In addition, an additional electrode 88h extends in the X direction, similarly to an additional electrode 88e. In addition, an additional electrode 88i extends in the X direction, similarly to an additional electrode 88f. In addition, the additional electrode 98a extends in the −X direction (direction opposite to the X direction), similarly to an additional electrode 98d. The additional electrode 98b extends in the −X direction, similarly to an additional electrode 98e. The additional electrode 98c extends in the −X direction, similarly to an additional electrode 98f.

The ground electrode 86a, the first through hole 50a, the deflection electrode 84a, the ground electrode 86b, the first through hole 50b, and the deflection electrode 84b are provided in order so as to be side by side in the X direction. The additional electrode 88a is connected to the ground electrode 86a and extends in the X direction. The additional electrode 88d is connected to the ground electrode 86b and extends in the X direction. Here, the additional electrode 88a and the additional electrode 88d are provided on the same straight line parallel to the X direction. Then, the additional electrode 88a and the additional electrode 88d are spaced apart from each other by a spacing portion 89a in the vicinity of the first deflection electrode 84a.

The ground electrode 96a, the second through hole 52a, the deflection electrode 94a, the ground electrode 96b, the second through hole 52b, and the deflection electrode 94b are respectively provided on the ground electrode 86a, the first through hole 50a, the deflection electrode 84a, the ground electrode 86b, the first through hole 50b, and the deflection electrode 84b. The second through hole 52 is positioned vertically corresponding to the first through hole 50. In other words, the second through hole 52 is substantially at the same position as the first through hole 50 when viewed from above. The additional electrode 98a is connected to the ground electrode 96a and extends in the −X direction. The additional electrode 98d is connected to the ground electrode 96b and extends in the −X direction. Here, the additional electrode 98a and the additional electrode 98d are provided on the same straight line parallel to the X direction. Then, the additional electrode 98a and the additional electrode 98d are spaced apart from each other by a spacing portion 99a in the vicinity of the ground electrode 96a.

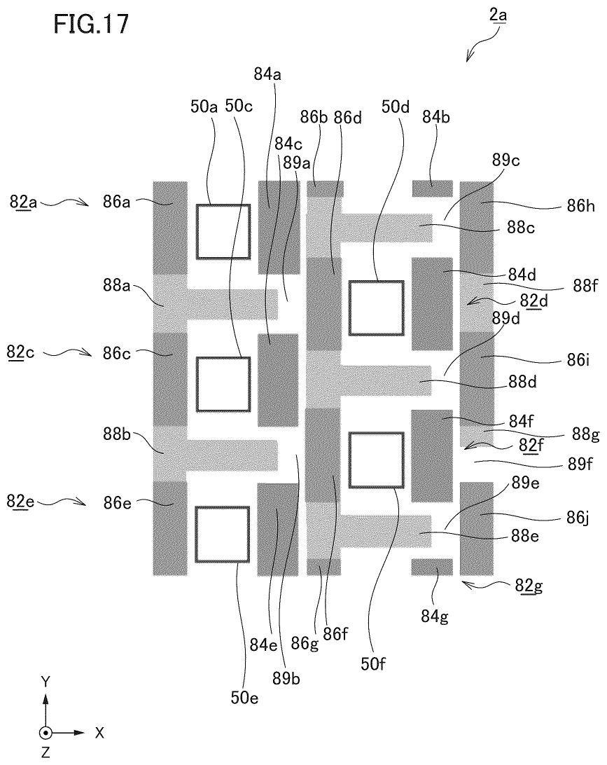

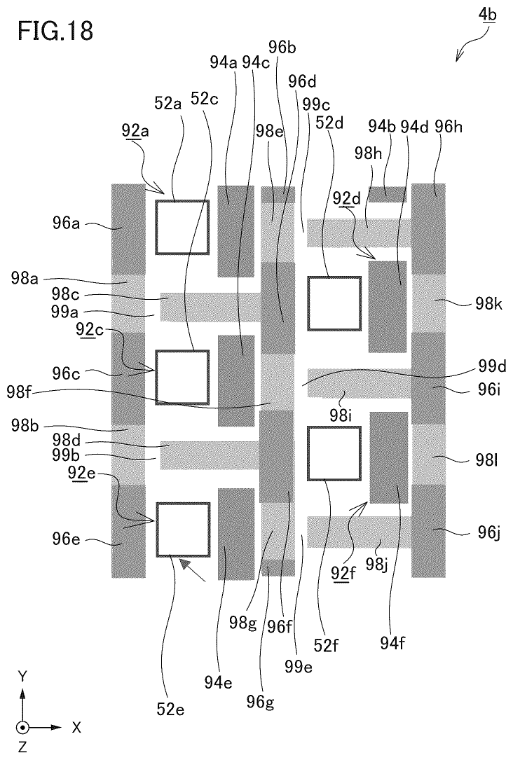

In addition, although the through holes are arranged in the direction of 90° on the plane in FIGS. 15 and 16, embodiments are not limited to this, and the same applies to a case where the through holes are arranged in the direction of 45° on the plane (FIGS. 17 and 18).

The first through hole 50e and the first through hole 50c are provided side by side in the Y direction so as to be spaced apart from each other. The first through hole 50f is provided between the first through hole 50e and the first through hole 50c in the Y direction. In addition, the first through hole 50e and the first through hole 50f are provided side by side in the X direction so as to be spaced apart from each other. The ground electrode 86e, the first through hole 50e, and the deflection electrode 84e are provided in order side by side in the X direction so as to be spaced apart from each other. The ground electrode 86c, the first through hole 50c, and the deflection electrode 84a are provided in order side by side in the X direction so as to be spaced apart from each other. The ground electrode 86f, the first through hole 50f, and the deflection electrode 88g are provided in order side by side in the X direction so as to be spaced apart from each other. The ground electrode 86f is provided so as to be spaced apart from the deflection electrode 84e and the deflection electrode 84c. The additional electrode 88b is connected to the ground electrode 86e and the ground electrode 86c, and is provided between the first through hole 50c and the first through hole 50e. Then, the tip of the additional electrode 88b is provided between the deflection electrode 84e and the deflection electrode 84c, and is spaced apart from the deflection electrode 84e, the deflection electrode 84c, and the ground electrode 86f by a spacing portion 89b.

The second through hole 52 is positioned vertically corresponding to the first through hole 50. In other words, the second through hole 52 is substantially at the same position as the first through hole 50 when viewed from above. The second through hole 52e is provided on the first through hole 50e. The second through hole 52c is provided on the first through hole 50c. The second through hole 52f is provided on the first through hole 50f. The deflection electrode 94e is provided on the deflection electrode 84e. The deflection electrode 94c is provided on the deflection electrode 84c. The ground electrode 96e is provided on the ground electrode 86e. The ground electrode 96h is provided on the ground electrode 86h. The ground electrode 96f is provided on the ground electrode 86f. The additional electrode 98e is connected to the ground electrode 96b and the ground electrode 96d, is provided between the deflection electrode 94a and the additional electrode 98h, and is provided so as to be spaced apart from the deflection electrode 94a and the additional electrode 98h.

Although the example in which notches are formed at two adjacent places of the additional electrode has been described above, the positions of the notches are not limited to this. Even in the case of a pattern in which notches are formed at two places on a diagonal line, the effect of suppressing the distortion of the drawing pattern can be obtained by adopting the same arrangement.

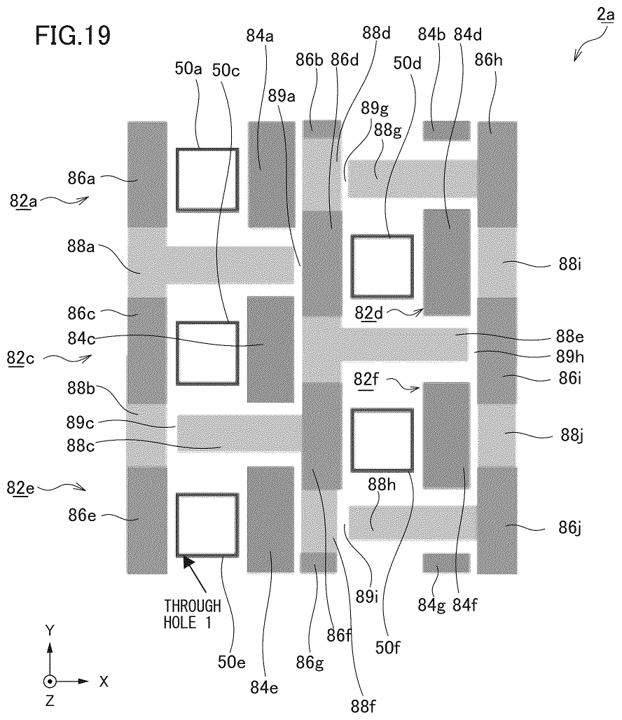

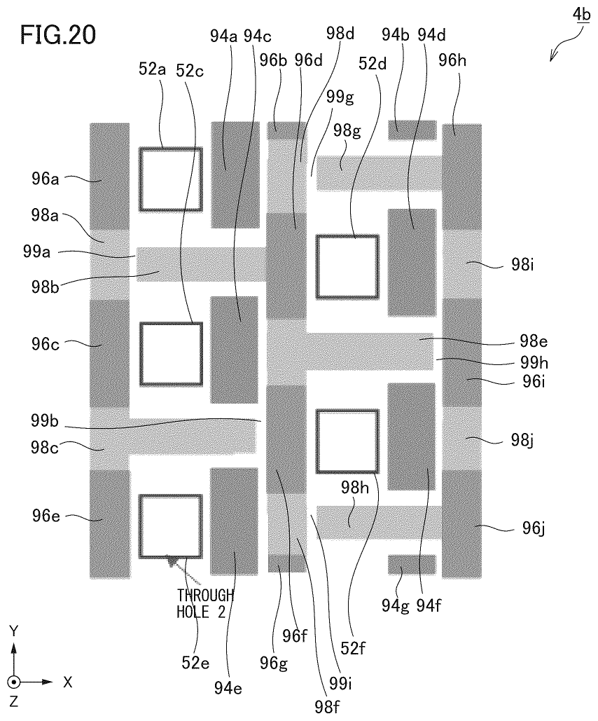

An example is shown in FIGS. 19 and 20. This is a case where through holes are arranged in the direction of 45°. This is an example in which, when two chips overlapping each other are viewed from above the chip 2, the ground electrode and the additional electrode pattern formed by the two chips surround the deflection electrode when the electrode patterns are projected. Here, the second through hole 52 is positioned vertically corresponding to the first through hole 50. In other words, the second through hole 52 is substantially at the same position as the first through hole 50 when viewed from above.

Each deflection electrode 94 is provided on each deflection electrode 84. Each ground electrode 96 is provided on each ground electrode 86. Each second through hole 52 is provided on each first through hole 50.

The additional electrode 88b is provided between the ground electrode 86c and the ground electrode 86e, and is connected to the ground electrode 86c and the ground electrode 86e. The additional electrode 88c is provided between the first through hole 50c and the first through hole 50e and between the deflection electrode 84c and the deflection electrode 84e, is connected to the ground electrode 86f, and is spaced apart from the additional electrode 88b by the spacing portion 89c.

The additional electrode 88a is provided between the ground electrode 86a and the ground electrode 86c, and is connected to the ground electrode 86a and the ground electrode 86c. In addition, the additional electrode 88a is provided between the first through hole 50a and the first through hole 50c and between the deflection electrode 84a and the deflection electrode 84c, and is spaced apart from the ground electrode 86d by the spacing portion 89a.

The additional electrode 98c is provided between the ground electrode 96c and the ground electrode 96e, and is connected to the ground electrode 96c and the ground electrode 96e. In addition, the additional electrode 98c is provided between the second through hole 52c and the second through hole 52e and between the deflection electrode 94c and the deflection electrode 94e, and is spaced apart from the ground electrode 96f by the spacing portion 99b.

The additional electrode 98b is provided between the second through hole 52a and the second through hole 52c and between the deflection electrode 94a and the deflection electrode 94c, is connected to the ground electrode 96d, and is spaced apart from the additional electrode 98a by the spacing portion 99a.

Even in a case where notches are formed at two places on the diagonal line of the additional electrode and through holes are arranged in the direction of 90°, the same arrangement is possible. Therefore, there is an effect of suppressing the distortion of the drawing pattern.

The requirements for embodiments are that when the pattern formed by the ground electrode and the additional electrode is viewed from the direction of the arrow on the upper side (from above the chip 2) in FIG. 5, the pattern formed by the ground electrode and the additional electrode formed on the first substrate surface and the fourth substrate surface is arranged so as to surround the deflection electrode when the electrode patterns are projected downward, and various modifications can be made.

In embodiments, the X direction is an example of a fourth direction, the Y direction is an example of a fifth direction perpendicular to the fourth direction, and the −X direction is an example of a sixth direction opposite to the fourth direction.

According to the semiconductor device of embodiments as well, it is possible to provide a semiconductor device with easy electrical connection.

While certain embodiments have been described, these embodiments have been presented by way of example only, and are not intended to limit the scope of the inventions. Indeed, the semiconductor device described herein may be embodied in a variety of other forms; furthermore, various omissions, substitutions and changes in the form of the devices and methods described herein may be made without departing from the spirit of the inventions. The accompanying claims and their equivalents are intended to cover such forms or modifications as would fall within the scope and spirit of the inventions.

In addition, embodiments described above can be summarized as the following technical proposals.

### (Technical Proposal 1)

A semiconductor device, comprising:

a first chip having a first substrate surface, a second substrate surface provided on a side opposite to the first substrate surface, and a plurality of first through holes, a plurality of charged particle beams passing through the first through holes;

a second chip provided on the first chip and having a third substrate surface facing the second substrate surface, a fourth substrate surface, and a plurality of second through holes provided on the first through holes, the charged particle beams passing through the second through holes;

a plurality of first electrodes provided on the first substrate surface so as to be adjacent to the first through holes;

a plurality of second electrodes provided on the first substrate surface;

a plurality of third electrodes provided on the fourth substrate surface so as to be adjacent to the second through holes; and

a plurality of fourth electrodes provided on the fourth substrate surface,

wherein the first electrodes are a first pair of electrodes for deflecting the charged particle beams,

the third electrodes are a second pair of electrodes for deflecting the charged particle beams,

the second electrode and the fourth electrode are additional electrode patterns other than the first pair of electrodes and the second pair of electrodes for deflecting the charged particle beams, and

an electrode pattern formed by the first electrode and the second electrode on the first substrate surface and an electrode pattern formed by the third electrode and the fourth electrode on the fourth substrate surface are not symmetrical with respect to opposite substrate surfaces of the two chips.

### (Technical Proposal 2)

The semiconductor device according to Technical Proposal 1,

wherein the second electrodes provided on the first substrate surface are a plurality of first pads electrically connected to the first electrodes,

the fourth electrodes provided on the fourth substrate surface are a plurality of second pads electrically connected to the third electrodes,

the first and second pads are arranged so as not to overlap each other when viewed from an upper surface of the second chip, the first chip and the second chip are held by a support, and

the first and second pads are connected to pads provided on the support.

### (Technical Proposal 3)

The semiconductor device according to Technical Proposal 2,

wherein the first and second pads are electrically connected to the pads provided on the support by using a plurality of wires.

### (Technical Proposal 4)

The semiconductor device according to Technical Proposal 2,

wherein the support has pads provided on a first surface facing the first substrate surface, and is electrically connected to the first pads through a plurality of bumps.

### (Technical Proposal 5)

The semiconductor device according to Technical Proposal 1,

wherein the first chip has a plurality of first pads provided on the second substrate surface, a plurality of second pads provided on the second substrate surface and a plurality of vias penetrating the first chip, and,

the first and the second pads are electrically connected to the pads provided on a support by using a plurality of wires.

### (Technical Proposal 6)

The semiconductor device according to Technical Proposal 2,

wherein the first chip has a rectangular shape,

the second chip has a rectangular shape,

the first pads are provided side by side at an end portion along a first direction parallel to the first substrate surface, and

the second pads are provided side by side at an end portion along a second direction parallel to the fourth substrate surface and crossing the first direction.

### (Technical Proposal 7)

The semiconductor device according to Technical Proposal 3,

wherein the first chip has a rectangular shape,

the second chip has a rectangular shape,

the first pads are provided side by side at an end portion along a first direction parallel to the first substrate surface, and

the second pads are provided side by side at an end portion along a second direction parallel to the fourth substrate surface and crossing the first direction.

### (Technical Proposal 8)

The semiconductor device according to Technical Proposal 4,

wherein the first chip has a rectangular shape,

the second chip has a rectangular shape,

the first pads are provided side by side at an end portion along a first direction parallel to the first substrate surface, and

the second pads are provided side by side at an end portion along a second direction parallel to the fourth substrate surface and crossing the first direction.

### (Technical Proposal 9)

The semiconductor device according to Technical Proposal 5,

wherein the first chip has a rectangular shape,

the second chip has a rectangular shape,

the first pads are provided side by side at an end portion along a first direction parallel to the second substrate surface, and

the second pads are provided side by side at an end portion along a second direction parallel to the fourth substrate surface and crossing the first direction.

### (Technical Proposal 10)

The semiconductor device according to Technical Proposal 1,

wherein each of the first electrodes includes a pair of deflection electrode and ground electrode, a voltage being applied to the pair of deflection electrode and ground electrode,

the second electrodes are arranged so as to surround at least some of the deflection electrodes of the first electrodes and the first through holes,

each of the third electrodes includes a pair of deflection electrode and ground electrode, a voltage being applied to the pair of deflection electrode and ground electrode, and

the fourth electrodes are arranged so as to surround at least some of the deflection electrodes of the third electrodes and the second through holes.

### (Technical Proposal 11)

The semiconductor device according to Technical Proposal 1,

wherein each of the first electrodes includes a pair of deflection electrode and ground electrode, a voltage being applied to the pair of deflection electrode and ground electrode,

each of the third electrodes includes a pair of deflection electrode and ground electrode, a voltage being applied to the pair of deflection electrode and ground electrode, and

a pattern formed by the ground electrodes of the first electrodes and the second electrodes or a pattern formed by the ground electrodes of the third electrodes and the fourth electrodes surrounds the deflection electrodes of the first electrodes, the deflection electrodes of the third electrodes, the first through holes, and the second through holes when viewed from above the second chip.

### (Technical Proposal 12)

The semiconductor device according to Technical Proposal 1,

wherein each of the first electrodes includes a pair of deflection electrode and ground electrode, a voltage being applied to the pair of deflection electrode and ground electrode,

each of the third electrodes includes a pair of deflection electrode and ground electrode, a voltage being applied to the pair of deflection electrode and ground electrode,

the second electrodes are connected to the ground electrodes of the first electrodes, and

the fourth electrodes are connected to the ground electrodes of the third electrodes.

### (Technical Proposal 13)

The semiconductor device according to Technical Proposal 10,

wherein each of the first electrodes includes a pair of deflection electrode and ground electrode, a voltage being applied to the pair of deflection electrode and ground electrode,

each of the third electrodes includes a pair of deflection electrode and ground electrode, a voltage being applied to the pair of deflection electrode and ground electrode,

the first through holes and the second through holes are positioned vertically corresponding to each other, and

a pattern formed by the ground electrodes of the third electrodes and the fourth electrodes provided on the fourth substrate has a shape obtained by rotating a pattern formed by the ground electrodes of the first electrodes and the second electrodes provided on the first substrate by 180 degrees within a plane parallel to the fourth substrate surface when viewed from an upper surface of the second chip.

### (Technical Proposal 14)

The semiconductor device according to Technical Proposal 11,

wherein each of the first electrodes includes a pair of deflection electrode and ground electrode, a voltage being applied to the pair of deflection electrode and ground electrode,

each of the third electrodes includes a pair of deflection electrode and ground electrode, a voltage being applied to the pair of deflection electrode and ground electrode,

the first through holes and the second through holes are positioned vertically corresponding to each other, and

a pattern formed by the ground electrodes of the third electrodes and the fourth electrodes provided on the fourth substrate has a shape obtained by rotating a pattern formed by the ground electrodes of the first electrodes and the second electrodes provided on the first substrate by 180 degrees within a plane parallel to the fourth substrate surface when viewed from an upper surface of the second chip.

### (Technical Proposal 15)

The semiconductor device according to Technical Proposal 12,

wherein each of the first electrodes includes a pair of deflection electrode and ground electrode, a voltage being applied to the pair of deflection electrode and ground electrode,

each of the third electrodes includes a pair of deflection electrode and ground electrode, a voltage being applied to the pair of deflection electrode and ground electrode,

the first through holes and the second through holes are positioned vertically corresponding to each other, and

a pattern formed by the ground electrodes of the third electrodes and the fourth electrodes provided on the fourth substrate has a shape obtained by rotating a pattern formed by the ground electrodes of the first electrodes and the second electrodes provided on the first substrate by 180 degrees within a plane parallel to the fourth substrate surface when viewed from an upper surface of the second chip.

### (Technical Proposal 16)

The semiconductor device according to Technical Proposal 1,

wherein the second substrate surface and the third substrate surface are in contact with each other.

### (Technical Proposal 17)

The semiconductor device according to Technical Proposal 1,

wherein trajectories of the charged particle beams are controlled.

What is claimed is:

1. A semiconductor device, comprising:
a first chip having a first substrate surface, a second substrate surface provided on a side opposite to the first substrate surface, and a plurality of first through holes, a plurality of charged particle beams passing through the first through holes;
a second chip provided on the first chip and having a third substrate surface facing the second substrate surface, a fourth substrate surface, and a plurality of second through holes provided on the first through holes, the charged particle beams passing through the second through holes;
a plurality of first electrodes provided on the first substrate surface so as to be adjacent to the first through holes;
a plurality of second electrodes provided on the first substrate surface;
a plurality of third electrodes provided on the fourth substrate surface so as to be adjacent to the second through holes; and
a plurality of fourth electrodes provided on the fourth substrate surface,
wherein the first electrodes are a first pair of electrodes for deflecting the charged particle beams,
the third electrodes are a second pair of electrodes for deflecting the charged particle beams,
the second electrode and the fourth electrode are additional electrode patterns other than the first pair of electrodes and the second pair of electrodes for deflecting the charged particle beams, and
an electrode pattern formed by the first electrode and the second electrode on the first substrate surface and an electrode pattern formed by the third electrode and the fourth electrode on the fourth substrate surface are not symmetrical with respect to opposite substrate surfaces of the two chips.

2. The semiconductor device according to claim 1,
wherein the second electrodes provided on the first substrate surface are a plurality of first pads electrically connected to the first electrodes,
the fourth electrodes provided on the fourth substrate surface are a plurality of second pads electrically connected to the third electrodes,
the first and second pads are arranged so as not to overlap each other when viewed from an upper surface of the second chip, the first chip and the second chip are held by a support, and
the first and second pads are connected to pads provided on the support.

3. The semiconductor device according to claim 2,
wherein the first and second pads are electrically connected to the pads provided on the support by using a plurality of wires.

4. The semiconductor device according to claim 2,
wherein the support has pads provided on a first surface facing the first substrate surface, and is electrically connected to the first pads through a plurality of bumps.

5. The semiconductor device according to claim 1,
wherein the first chip has a plurality of first pads provided on the second substrate surface, a plurality of second pads provided on the second substrate surface and a plurality of vias penetrating the first chip, and,
the first and the second pads are electrically connected to the pads provided on a support by using a plurality of wires.

6. The semiconductor device according to claim 2,
wherein the first chip has a rectangular shape,
the second chip has a rectangular shape,
the first pads are provided side by side at an end portion along a first direction parallel to the first substrate surface, and
the second pads are provided side by side at an end portion along a second direction parallel to the fourth substrate surface and crossing the first direction.

7. The semiconductor device according to claim 3,
wherein the first chip has a rectangular shape,
the second chip has a rectangular shape,
the first pads are provided side by side at an end portion along a first direction parallel to the first substrate surface, and
the second pads are provided side by side at an end portion along a second direction parallel to the fourth substrate surface and crossing the first direction.

8. The semiconductor device according to claim 4,
wherein the first chip has a rectangular shape,
the second chip has a rectangular shape,
the first pads are provided side by side at an end portion along a first direction parallel to the first substrate surface, and
the second pads are provided side by side at an end portion along a second direction parallel to the fourth substrate surface and crossing the first direction.

9. The semiconductor device according to claim 5,
wherein the first chip has a rectangular shape,
the second chip has a rectangular shape,
the first pads are provided side by side at an end portion along a first direction parallel to the second substrate surface, and
the second pads are provided side by side at an end portion along a second direction parallel to the fourth substrate surface and crossing the first direction.

10. The semiconductor device according to claim 1,
wherein each of the first electrodes includes a pair of deflection electrode and ground electrode, a voltage being applied to the pair of deflection electrode and ground electrode,
the second electrodes are arranged so as to surround at least some of the deflection electrodes of the first electrodes and the first through holes,
each of the third electrodes includes a pair of deflection electrode and ground electrode, a voltage being applied to the pair of deflection electrode and ground electrode, and
the fourth electrodes are arranged so as to surround at least some of the deflection electrodes of the third electrodes and the second through holes.

11. The semiconductor device according to claim 1,
wherein each of the first electrodes includes a pair of deflection electrode and ground electrode, a voltage being applied to the pair of deflection electrode and ground electrode,
each of the third electrodes includes a pair of deflection electrode and ground electrode, a voltage being applied to the pair of deflection electrode and ground electrode, and
a pattern formed by the ground electrodes of the first electrodes and the second electrodes or a pattern formed by the ground electrodes of the third electrodes and the fourth electrodes surrounds the deflection electrodes of the first electrodes, the deflection electrodes of the third electrodes, the first through holes, and the second through holes when viewed from above the second chip.

12. The semiconductor device according to claim 1,
wherein each of the first electrodes includes a pair of deflection electrode and ground electrode, a voltage being applied to the pair of deflection electrode and ground electrode,
each of the third electrodes includes a pair of deflection electrode and ground electrode, a voltage being applied to the pair of deflection electrode and ground electrode,
the second electrodes are connected to the ground electrodes of the first electrodes, and
the fourth electrodes are connected to the ground electrodes of the third electrodes.

13. The semiconductor device according to claim 10,
wherein each of the first electrodes includes a pair of deflection electrode and ground electrode, a voltage being applied to the pair of deflection electrode and ground electrode,
each of the third electrodes includes a pair of deflection electrode and ground electrode, a voltage being applied to the pair of deflection electrode and ground electrode,
the first through holes and the second through holes are positioned vertically corresponding to each other, and
a pattern formed by the ground electrodes of the third electrodes and the fourth electrodes provided on the fourth substrate has a shape obtained by rotating a pattern formed by the ground electrodes of the first electrodes and the second electrodes provided on the first substrate by 180 degrees within a plane parallel to the fourth substrate surface when viewed from an upper surface of the second chip.

14. The semiconductor device according to claim 11,
wherein each of the first electrodes includes a pair of deflection electrode and ground electrode, a voltage being applied to the pair of deflection electrode and ground electrode,
each of the third electrodes includes a pair of deflection electrode and ground electrode, a voltage being applied to the pair of deflection electrode and ground electrode,
the first through holes and the second through holes are positioned vertically corresponding to each other, and
a pattern formed by the ground electrodes of the third electrodes and the fourth electrodes provided on the fourth substrate has a shape obtained by rotating a pattern formed by the ground electrodes of the first electrodes and the second electrodes provided on the first substrate by 180 degrees within a plane parallel to the fourth substrate surface when viewed from an upper surface of the second chip.

15. The semiconductor device according to claim 12,
wherein each of the first electrodes includes a pair of deflection electrode and ground electrode, a voltage being applied to the pair of deflection electrode and ground electrode,
each of the third electrodes includes a pair of deflection electrode and ground electrode, a voltage being applied to the pair of deflection electrode and ground electrode,
the first through holes and the second through holes are positioned vertically corresponding to each other, and
a pattern formed by the ground electrodes of the third electrodes and the fourth electrodes provided on the fourth substrate has a shape obtained by rotating a pattern formed by the ground electrodes of the first electrodes and the second electrodes provided on the first substrate by 180 degrees within a plane parallel to the fourth substrate surface when viewed from an upper surface of the second chip.

16. The semiconductor device according to claim 1,
wherein the second substrate surface and the third substrate surface are in contact with each other.

17. The semiconductor device according to claim 1,
wherein trajectories of the charged particle beams are controlled.
